(19) United States
(12) Patent Application Publication
(10) Pub. No.: US 2026/0127345 A1
(43) Pub. Date: May 7, 2026

(54) DEVELOPING A DESIGN OF AN ELECTRONIC CIRCUIT SYSTEM IN EDA ENVIRONMENT

(71) Applicant: International Business Machines Corporation, Armonk, NY (US)

(72) Inventors: Tobias Werner, Weil im Schoenbuch (DE); Davide Fiorentini, Sindelfingen (DE); Ralf Richter, Unterhausen (DE); Iris Maria Leefken, Dettenhausen (DE)

(21) Appl. No.: 19/042,447

(22) Filed: Jan. 31, 2025

(30) Foreign Application Priority Data
Nov. 6, 2024 (GB) 2416321.4

(51) Int. Cl. G06F 30/33; G06F 30/323

(52) U.S. Cl. CPC G06F 30/33; G06F 30/323

(57) ABSTRACT

The present disclosure relates to a method for developing a design of an electronic circuit system in one or more Electronic Design Automation (EDA) environments. The method comprises: receiving data indicative of an event related to a specific point in time during development of the design of the electronic circuit system using a first software tool. A development action may be determined based on the event. Design data descriptive of a state of the design at the point in time, and a library setup descriptive of libraries used by the first software tool to provide the design at that state may be determined. A design snapshot data structure comprising entries representing the design data and the library setup may be created. The design snapshot data structure may be shared with a second software tool for enabling execution of the development action using the second software tool.

### BACKGROUND

The present invention relates to the field of digital computer systems, and more specifically, to a method for developing a design of an electronic circuit system in Electronic Design Automation (EDA) environments.

In electronic circuit design, especially for large and complex systems, collaboration between multiple team members is critical. This is often achieved using specialized software tools that allow designers to work simultaneously on different aspects of a project. Central to this process is the concept of a hierarchical design, where circuits are broken down into modules, with a top cell representing the highest level of the design. However, there is a need for improved processes for circuit design development.

### SUMMARY

Various embodiments provide methods for developing a design of an electronic circuit system in one or more EDA environments, computer program products, database and systems as described by the subject matter of the independent claims. Advantageous embodiments are described in the dependent claims. Embodiments of the present invention can be freely combined with each other if they are not mutually exclusive.

In one aspect, the invention relates to a method (first method) for developing a design of an electronic circuit system in one or more EDA environments; the method comprising: receiving data indicative of an event related to a specific point in time during development of the design of the electronic circuit system using a first software tool; determining a development action based on the event; determining design data descriptive of a state the design at the point in time, and determining a library setup descriptive of libraries used by the first software tool to provide the design at that state; creating a design snapshot data structure comprising the design data and the library setup; sharing the design snapshot data structure with a second software tool for enabling execution of the development action using the second software tool.

In one aspect the invention relates to a computer program product comprising a computer-readable storage medium having computer-readable program code embodied therewith, the computer-readable program code configured for: receiving data indicative of an event related to a specific point in time during development of the design of the electronic circuit system using a first software tool; determining a development action based on the event; determining design data descriptive of a state the design at the point in time, and determining a library setup descriptive of libraries used by the first software tool to provide the design at that state; creating a design snapshot data structure comprising the design data and the library setup; sharing the design snapshot data structure with a second software tool for enabling execution of the development action using the second software tool.

In one aspect the invention relates to a computer system for developing a design of an electronic circuit system in one or more EDA environments; the computer system comprising a first software tool; the computer system being configured for: receiving data indicative of an event related to a specific point in time during development of the design of the electronic circuit system using the first software tool; determining a development action based on the event; determining design data descriptive of a state of the design at the point in time, and determining a library setup descriptive of libraries used by the first software tool to provide the design at that state; creating a design snapshot data structure comprising the design data and the library setup; sharing the design snapshot data structure with a second software tool for enabling execution of the development action using the second software tool.

In one aspect the invention relates to a database comprising multiple computer implemented data structures, wherein each computer implemented data structure is adapted for performing a development action on a design of an electronic circuit system, the data structure comprising design data and a library setup for opening the design, the design data being descriptive of a state of the design at the time of the development action, the library setup being descriptive of libraries used by the design data.

### BRIEF DESCRIPTION OF THE DRAWINGS

In the following embodiments of the invention are explained in greater detail, by way of example only, making reference to the drawings in which:

FIG. 1 depicts a block diagram of an electronic circuit system design collaboration system according to an example of the present subject matter.

FIG. 2 is a flowchart of a method for developing a design of an electronic circuit system using a software tool in a design team according to an example of the present subject matter.

FIG. 3 is a flowchart of a method for performing a development action on a design of an electronic circuit system using a software tool according to an example of the present subject matter.

FIG. 4 depicts a diagram that represents a design snapshot data structure in accordance with an example of the present subject matter.

FIG. 5 is a computing environment in accordance with an example of the present subject matter.

### DETAILED DESCRIPTION

The descriptions of the various embodiments of the present invention will be presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The present subject matter may enable an improved synchronization across different software tools in the same or different EDA environments. By capturing and sharing a design snapshot, including design data and library setups, at a specific point in time, the present subject matter may ensure that the second software tool can replicate the exact design environment and state. This may enhance consistency and accuracy, allowing seamless continuation of development actions without discrepancies between tools. Additionally, traceability may be improved through event-based snapshots, enabling users to revisit specific moments in the design process and ensuring better version control and error tracking. Additionally, event-based snapshots may be automatically generated in response to key milestones or changes in the design process, ensuring they capture critical moments like modifications, errors, or approvals. The automation of this process may reduce manual effort, leading to increased efficiency and minimizing the potential for errors in replicating the design environment.

“First,” “Second,” etc. as used herein, these terms are used as labels for nouns that they precede, and do not imply any type of ordering (e.g., spatial, temporal, logical) unless explicitly defined as such.

The design of the electronic circuit system may be created and developed using a first software tool of a first EDA environment. A user or a developer may be controlling or monitoring the development of the design of the electronic circuit system. This user may be referred to as a first user. For example, the first user may launch the execution of the first software tool on a first computer system of the first user. The electronic circuit system may refer to a set of interconnected components designed to work together to perform a specific function, typically through the processing, control, or transmission of electrical signals. The electronic circuit system may, for example, be an integrated circuit (IC) such as a microprocessor IC.

The EDA environment may refer to a software ecosystem that provides tools, methodologies, and frameworks for designing, simulating, verifying, and optimizing electronic circuits and systems. It encompasses software solutions that support various aspects of the integrated circuit and electronic system design flow, from conceptual design and schematic capture to layout, physical implementation, verification, and final signoff. The software tool may be a component of the EDA environment, providing features for interactive layout design and verification. For example, the software tool may be an IC development tool, within the EDA environment, for creating, editing, and verifying the design of integrated circuits. The instance of the software tool may refer to a specific occurrence or running copy of that software tool in a particular system. Each instance of the software tool may operate independently. Multiple instances of the software tool may exist simultaneously, each potentially performing different actions or working on separate tasks. For example, if the software tool is opened on two different computer systems, each may represent a separate instance of the software tool, operating with its own state and data.

The design may refer to a representation of the electronic circuit system within a computer system. The design developed using the software tool may be further utilized in other stages within the EDA environment. These other stages may include physical verification, performance validation through simulation, such as a simulation to assess the design after completing the physical layout, and timing analysis. The design may be provided with a view capturing a specific perspective of the design. For example, a schematic view of the design may represent the logical or functional diagram of the electronic circuit system, showing how components like transistors, resistors, and capacitors are connected electrically. A layout view of the design may be the physical representation, detailing the actual geometric arrangement of components and wiring on a chip or printed circuit board (PCB), which may be critical for fabrication. A symbol view of the design may simplify complex components or circuits into a single block symbol for use in higher-level designs. A netlist view of the design may list the electronic circuit system elements and their connections in a text-based format, often used for simulation or verification. These views work together to ensure that the design is functionally correct, optimized for performance, and ready for fabrication. Using any of the views, the design may serve as the foundational framework from which the final product or solution may be developed.

An event related to a specific point in time during development of the design of the electronic circuit system using the first software tool may be received by the first computer system. The event may refer to a significant occurrence, while the “point in time” may mark when it happens in the development timeline. In one example, the event may be time-triggered. For example, the event may be defined by pre-scheduled milestones such as design reviews or testing deadlines. Additionally, or alternatively, the event may be action-triggered, initiated by a specific action or change, like a modification in the design, detection of an error, or approval of a design element. Additionally, or alternatively, the event may be triggered by external conditions, such as the completion of a simulation, availability of resources, or feedback from one or more users such as the first user. In all cases, the “specific point in time” may serve as a precise marker, ensuring accurate recording of the event, improving traceability, and aligning it within the broader development timeline for better development management.

The reception of the event may comprise the reception of a description of the event. This description may be provided as input by the first user, in which case the event is triggered by the first user. Alternatively, the event may be automatically detected, such as through action-triggered or time-triggered mechanisms, by an event detection module within the software tool. In this scenario, the description of the event may be received from the event detection module. The description may be provided in a format that can be processed by the first computer system. The format of the event description may vary depending on the system's needs. The event description may be provided as a structured text file such as XML or JSON, providing key details like the event type, timestamp, user ID, and associated changes or actions taken. Alternatively, the description might be a log entry within a database, storing information like the event's unique ID, time of occurrence, and specific parameters or actions involved. Each format is designed to ensure the event description can be easily read, processed, or referenced by the first computer system for further actions or analysis.

A development action may be determined based on the received event. The development action may be determined by the first computer system using the received description of the event. The development action may align with the nature of the trigger of the event. For example, for a time-triggered event like design review or testing deadline, a development action may include initiating a formal review process or running automated tests. For an action-triggered event such as design modification, error detection, or approval, the development action may include the performance of the modification action or the debugging of the error. In the case of an externally triggered event like user requested action, the development action may comprise that user requested action. These actions may ensure the development process progresses efficiently and remain aligned with project goals.

The first computer system may automatically determine the development action based on the event description by, for example, using predefined rules and event-action mappings within the software tool. For example, the first computer system may parse the event description to identify key details, such as event type (e.g., design modification, error detection, or simulation completion), and match it to a corresponding action based on preprogrammed logic. For instance, if an error is detected, the first computer system may trigger debugging or alert relevant team members. The development action may, for example, comprise one or more computer executable instructions. Alternatively, the development action may be presented as a user prompt, such as a notification or alert within the software tool, providing details on the development action.

After determining the development action, design data descriptive of a state the design at the point in time, and a library setup descriptive of libraries used by the first software tool to provide the design at that state may be determined. For example, once the development action is determined, the next operation may be to capture the design data that describes the state of the design at that specific point in time e.g., including all relevant information such as the components used, their interconnections, and other design parameters. Capturing this design state may enable developers to preserve a complete record of how the design looked and functioned at that point of time, providing a valuable snapshot that can be used for debugging, rollback, or further development without losing track of previous design versions. Alongside the design data, the method involves identifying the library setup, which refers to the libraries that the design depends on, such as component libraries, IP blocks, or other reusable assets. The library setup may document which libraries were used and in what configuration. By explicitly recording this information, developers may ensure that the design remains portable and can be accurately reconstructed on different systems. This approach may also help avoid compatibility issues, as all dependencies are clearly identified and can be tracked.

A design snapshot data structure comprising the design data and the library setup may be created. For example, after capturing the design data and library setup, the design snapshot data structure is created, serving as a record of the design at that specific point in time. This data structure may contain entries representing both the design data and the library setup, encapsulating the full state of the design at the specific point in time. The creation of this snapshot may allow the design state to be easily shared, stored, and retrieved later. It may act as a backup, enabling teams to revert to previous states if needed or transfer the design to other tools or collaborators without losing any fidelity.

The design snapshot data structure may be a data structure. The design snapshot data structure may be a representation that captures and stores the state of the design at the specific point in time. It may include all relevant information, such as the configuration, components, and any dependencies or libraries in use. The term “snapshot” may indicate that the data structure may allow developers or users to preserve the exact state of the design, enabling them to review, share, or revert to that specific version later without losing any data or context. Examples of design snapshot data structure may include array, linked list, tree, and graph, each may be suited to different types of operations and applications depending on factors like data organization, access speed, and memory usage. The design snapshot data structure may be formatted in a way that both the first and second software tools can decode and read it. The design snapshot data structure may have a predefined format which may be referred to as a standardized format because it ensures consistency and compatibility across different software tools and different EDA environments. This standardization may allow seamless integration, data exchange, and collaboration between various software tools.

The design snapshot data structure may be shared with a second software tool of a second EDA environment for enabling execution of the development action using the second software tool. For example, the design snapshot data structure is shared with the second software tool, which may involve transferring the design snapshot data structure to another developer or team working on a different machine or running the development action on another server or environment. For example, a second user may launch the execution of the second software tool on a second computer system of the second user. The second user may, for example, be a contributor to the design of the electronic circuit system or a debugger. Sharing the snapshot may ensure that all collaborators have access to the same design version, reducing errors and improving synchronization in large teams or distributed environments. The first and second EDA environments may be either the same or different, and if they are the same, they may represent one instance or separate instances of the EDA environment.

The second software tool may be used to carry out the development action based on the design snapshot data structure. In one example, the development action may be executed automatically on the second computer system, using the second software tool, immediately upon sharing the design snapshot. Alternatively, the second computer system may prompt the second user to perform the development action, and the action may then be completed by the second user using the second software tool.

According to one example, the first and second software tools are two instances of a software tool of the same EDA environment. That is, the first and second EDA environments are the same. Alternatively, the first and second software tools are different tools of different EDA environments. That is, the first and second EDA environments are different. When the first and second software tools are instances of the same software tool and same EDA environment, seamless integration and direct interoperability may be ensured, reducing the risk of data translation errors and enhancing consistency in the design process. Alternatively, if the first and second software tools belong to different EDA environments, this flexibility may allow for broader compatibility and collaboration across multiple platforms.

According to one example, the development action comprises at least one of: addressing a detected bug representing a design rule violation and/or a bug in the first software tool, or incorporating a contribution to the design. For example, the bug may manifest for the first time on the first computer system due to a specific configuration or design state. Alternatively, the first software tool may be continuing the development of a design initially started by another software tool. In this case, the bug could arise when opening the transferred design or during further development, potentially due to compatibility issues, differences in interpretation of the design data, or inconsistencies introduced during the handover between tools. Addressing the detected bug that represents the design rule violation or the bug in the first software tool may involve identifying and resolving them in the EDA environment. The design rule violation may occur when the design fails to adhere to specific guidelines or constraints set by the design process of the EDA environment, such as spacing requirements, minimum dimensions or maximum dimensions. In contrast, the bug may refer to an error or malfunction within the software tool, such as unexpected crashes, or command execution errors. Resolving these issues may involve modifying the design to comply with design rules or updating and debugging the software tool.

According to one example, the design snapshot data structure further comprises a metadata descriptive of the first software tool. The metadata may, for example, include a version of the first software tool or its configuration settings. This may allow for precise bug tracking and debugging by linking issues to specific software tool versions.

Indeed, the development action in the context of electronic circuit system design may involve tasks such as addressing a detected bug, or incorporating a contribution. For example, the addressing or fixing of the bug may ensure the integrity and reliability of the design, preventing it from failing in real-world applications. The addressing of the bug may also help maintain consistency in design functionality, preventing regressions. In another example, debugging a problem may entail a deeper investigation into specific issues that could be related to timing, functionality, or physical layout. Debugging may be necessary, for example, because in complex systems, problems may arise from unexpected interactions between components of the design. The debugging may, for example, enable to isolate the root cause of an issue to ensure that the design operates within its required parameters. In another example, incorporating a contribution may involve merging new design elements or improvements from the second user. This may ensure that collaborative development is streamlined and that the design may benefit from enhancements, optimizations, or additional functionality contributed by others.

According to one example, the sharing of the design snapshot data structure comprises any one of: storing the design snapshot data structure in a shared memory between the first and second software tools; and sending using a workplace messaging platform the design snapshot data structure to the second software tool.

The workplace messaging platform may be a digital communication tool designed to enable real-time messaging. The workplace messaging platform may, for example, allow for text-based chat, file sharing, and integration with other tools and software to streamline workflows. The workplace messaging platform may support both direct messages (one-on-one communication) and group conversations (team channels or group chats).

Both sharing methods may enable smooth collaboration by ensuring that the design snapshot data structure is consistently transferred, but the choice may depend on factors like proximity of the software tools, need for speed, and whether the collaboration is synchronous or asynchronous. For example, one option may be storing the design snapshot data structure in shared memory accessible by both the first and second software tools. This may enable high-speed access and minimal data transfer overhead, especially in environments where both tools are running on the same system or network. The shared memory may allow both tools to directly access the design snapshot data structure, ensuring synchronous updates and real-time collaboration. The alternative option may involve sending the design snapshot data structure via the workplace messaging platform to the second software tool. This approach may be motivated by the need for remote collaboration or when the tools are operating on different machines, e.g., in different geographic locations. Sending the design snapshot data structure through the workplace messaging platform may allow for easy sharing in distributed work setups, where team members might not have direct access to a shared memory environment. This method may also provide a record of the design snapshot data structures within the platform, which may be useful for tracking changes, version control, and facilitating asynchronous development workflows.

According to one example, the method further comprises: using the shared design snapshot data structure for creating a temporary library setup comprising the library setup by at least adding one or more libraries and/or updating one or more existing libraries of a second software tool, using the second software tool for opening the design using the design data and the temporary library setup, and performing using the second software tool the development action. This example may be executed at the second computer system of the second user and optionally further executed at other computer systems using respective software tool.

Indeed, using the shared design snapshot data structure may allow for the creation of the temporary library setup by adding or updating one or more libraries which are associated with or accessible by the second software tool. This temporary library setup may integrate the library setup from the shared design snapshot data structure, enabling the second software tool to open the design using the design data and the temporary library setup. The second software tool may then be used to perform the development action. The advantage of this process may be that it may ensure consistency in the design environment across multiple instances, allowing for collaborative work while accommodating necessary modifications. It may also avoid conflicts between library versions and maintain synchronization between different teams or systems.

According to one example, the creating of the temporary library setup and the opening of the design is automatically performed using a library manager that is configured to connect to the second software tool through an interface.

The second software tool of the second EDA environment may be used for designing and developing electronic circuit systems, such as ICs and printed circuit boards (PCBs). In this scenario, the process of creating the temporary library setup and opening the design may be handled automatically by the library manager. The library manager may be specifically configured to connect to the second software tool via the interface, allowing seamless integration of the design data and the necessary libraries with the second software tool. The library manager may ensure that the correct versions of the libraries are selected, whether they need to be added, updated, or replaced in the temporary library setup. This automatic management may save significant time and reduce the likelihood of human error, such as selecting incorrect library versions or misconfigurations. Additionally, it may ensure that the second software tool is working with the most accurate and compatible libraries.

According to one example, the interface is a web interface, wherein the shared design snapshot data structure is provided as a link to the interface, wherein the creating of the temporary library setup and the opening of the design is automatically performed in response to invoking the link.

The interface being a web interface may mean it operates through a browser or an internet-based application. The shared design snapshot data structure may be provided as a link within this web interface, simplifying access and usability. When the link is invoked (e.g., clicked), the process of creating the temporary library setup and opening the design may be automatically initiated. The advantage of using a web interface may be that it may provide platform-independent access, allowing users to easily access the design and its libraries from any location with internet access. The link-based approach may simplify collaboration by enabling teams to quickly share and open specific design states without needing to send large files or manually configure the environment.

In one example, the temporary library setup may be deleted after the development action is completed. The deletion may further comprise a restoring of the second software tool to its status before using the shared design snapshot data structure. This may ensure that unnecessary resources are not occupying storage and prevent potential conflicts with future designs. In another example, the temporary library setup may be maintained as a permanent configuration e.g., if the libraries are expected to be reused in subsequent development actions. This may avoid the need to recreate the setup each time and facilitate ongoing development without reconfiguring the library environment.

According to one example, the design data is descriptive of a first cell representing the design, wherein the library setup includes libraries for the first cell and one or more second cells representing components of the design, wherein the design represents the physical or logical design of an electronic circuit system.

In this example, the design data represents the first cell, which may serve as the core or primary element of the electronic circuit system's design, while the library setup may contain the necessary libraries for both this first cell and second cells, which represent sub-components of the design. Each second cell may act as a smaller building block that contributes to the overall electronic circuit system. By organizing the design into a main cell and supporting component cells, this approach may enhance modularity, making it easier to manage, modify, and understand complex designs.

According to one example, the libraries are determined by navigation in accordance with a design architecture of the design of the first and second cells.

The libraries associated with the design cells are identified by navigating the computer directories representing the architecture of the design. This navigation may thus be based on the architecture of the design, which outlines the structure and relationships between the first cell and the second cells. This design architecture may guide the selection of the appropriate libraries needed for each part of the design. This approach may also streamline the process by automating the selection of the right resources based on the design's internal structure, thereby improving both efficiency and consistency.

According to one example, the design architecture is a hierarchical architecture, wherein the first cell is a top level cell and the second cells are sub hierarchy cells, wherein the navigation is a hierarchical traversal starting from the first cell.

The design architecture in this example follows a hierarchical structure, where the first cell serves as the top-level cell, and the second cells function as sub-hierarchy cells. Navigation through the design occurs via hierarchical traversal, starting from the top-level cell and moving through its sub-cells. This hierarchical architecture may provide a clear and organized structure, with the top-level cell managing the overall system and sub-cells focusing on specific components. Hierarchical traversal may systematically manage complex designs, ensuring that dependencies between components are correctly handled.

According to one example, the first software tool is executed in the first computer system, and the second software tool is executed in the second computer system, wherein the first and second computer systems are collocated or remotely connected systems.

The first and second computer systems may either be collocated—situated in the same physical location—or they can be remotely connected through a network. This setup may allow the two systems to collaborate on the same design using shared data, even if they are geographically distant. The advantage of this configuration may be that it may provide flexibility in development environments. Collocated systems enable fast, high-bandwidth collaboration, ideal for environments where teams need to work closely together. Remotely connected systems may offer greater flexibility, enabling global collaboration across different time zones, reducing the need for physical proximity. This setup may support distributed development, allowing multiple team members to work on the same design without version conflicts. Additionally, it can help with load balancing by distributing intensive tasks across multiple systems.

According to one example, the library setup comprises paths and versions of the libraries. The libraries used within an EDA environment may be provided by the EDA vendor, sourced from open-source distributors, or created by users or companies working with the EDA tools. A library in the EDA environment may serve as a structured collection of design components, standard cells, process-specific technology files, and simulation models. These libraries may enable designers to access pre-defined elements, adhere to technology-specific design rules, and maintain consistency throughout the design and verification processes.

The paths may refer to the specific file locations or directories where the libraries are stored, while the versions may refer to the particular release or iteration of each library being used. This setup may be crucial for ensuring that the design has access to the correct libraries and dependencies necessary for it to function properly.

In one example, multiple design snapshot data structures may be created at different points of time using the first software tool or other software tools. For example, the multiple design snapshot data structures may be created for the development actions involving detected bugs. That is, each design snapshot data structure of the multiple design snapshot data structures may provide a state of the design of the electronic circuit system at the time of detecting a bug. That is, multiple bugs may be associated with the multiple design snapshot data structures. These design snapshot data structures may, for example, be collected in a database to enable other users to access them for performing development actions. For example, the database may comprise entries, wherein each entry may comprise a respective design snapshot data structure.

The database may be configured to handle development query searches, enabling users to identify data structures that correspond to the specified development stage. Upon receiving a query, the database processes the search by matching the query parameters with stored data structures and associated description.

In one example, the workplace messaging platform that is used to share the design snapshot data structures may comprise the database, where the design snapshot data structures are collected/maintained while being shared.

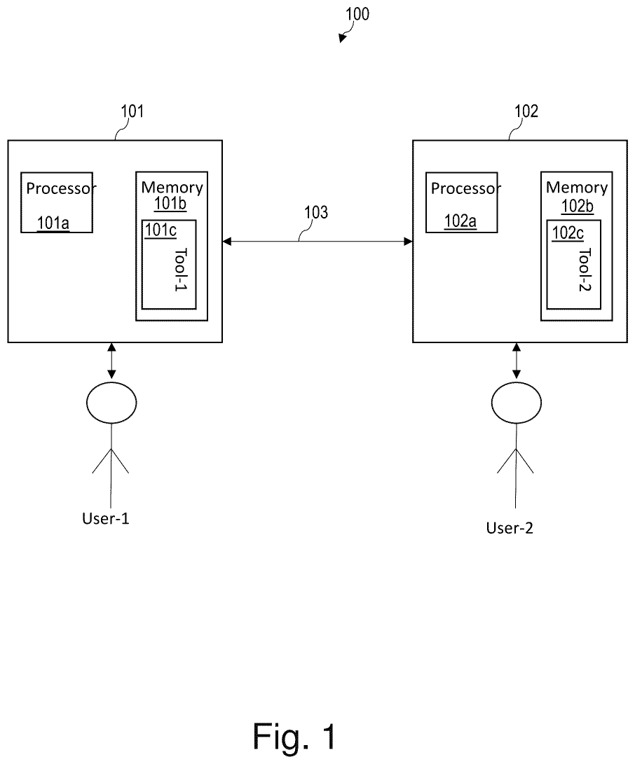

FIG. 1 depicts a block diagram of an electronic circuit system design collaboration system according to an example of the present subject matter.

The electronic circuit system design collaboration system 100 comprises a first computer system 101 and a second computer system 102. The first computer system 101 is configured to communicate with the second computer system 102 through a communication link 103. The communication link 103 enables synchronization and data exchange, allowing development actions or design updates from one system to be reflected on the other. The communication link 103 may be any type of network connection that enables data exchange, such as a Local Area Network (LAN) or Wide Area Network (WAN) for local or remote communication, Ethernet for wired connections, or Wi-Fi for wireless networking. Other options may include Bluetooth for short-range wireless communication, or optical fiber for high-speed, high-bandwidth data transfers over longer distances.

The first computer system 101 comprises a memory 101b and a processor 101a. The memory 101b comprises a first software tool 101c of a first EDA environment. The processor 101a may be configured to execute the first software tool 101c. The second computer system 102 comprises a memory 102b and a processor 102a. The memory 102b comprises a second software tool 102c of a second EDA environment. The processor 102a may be configured to execute the second software tool 102c. The first and second EDA environments may be either the same or different, and if they are the same, they may represent identical or separate instances of the environment.

Each user User-1 and User-2 interacts with their respective software tool (Tool-1 or Tool-2) to perform circuit design development actions. Users User-1 and User-2 may collaborate using the software tools on their respective systems. The first user User.1 may work with the first software tool 101c to develop a design of an electronic circuit system while the second user User-2 may work with the second software tool 102c e.g., to contribute to the development of the design of the electronic circuit system.

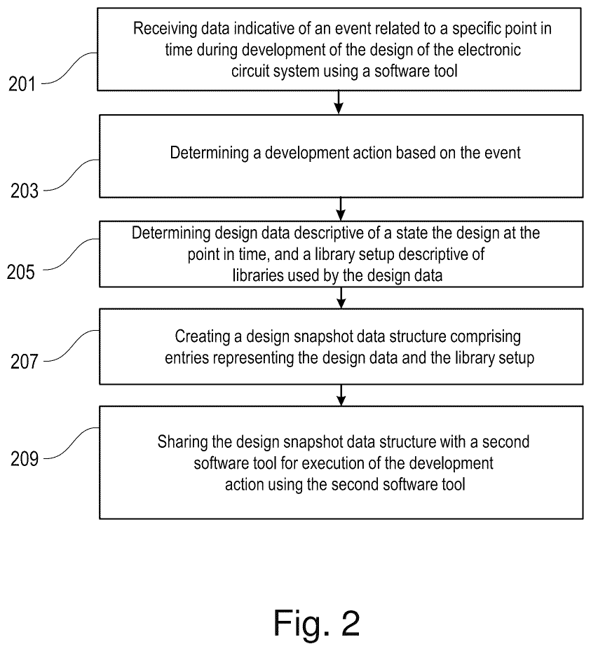

FIG. 2 is a flowchart of a method for developing a design of an electronic circuit system using a software tool in one or more EDA environments according to an example of the present subject matter. For the purpose of explanation, the method described in FIG. 2 may be implemented in the system illustrated in FIG. 1 but is not limited to this implementation. The method may, for example, be performed by the first computer system 101.

An event related to a specific point in time during development of the design of the electronic circuit system using a first software tool may be received in step 201.

A development action may be determined in step 203 based on the received event.

Design data descriptive of a state the design at the point in time and a library setup descriptive of libraries used by the design data may be determined in step 205.

A design snapshot data structure comprising entries representing the design data and the library setup may be created in step 207.

The design snapshot data structure may be shared in step 209 with a second software tool for execution of the development action using the second software tool.

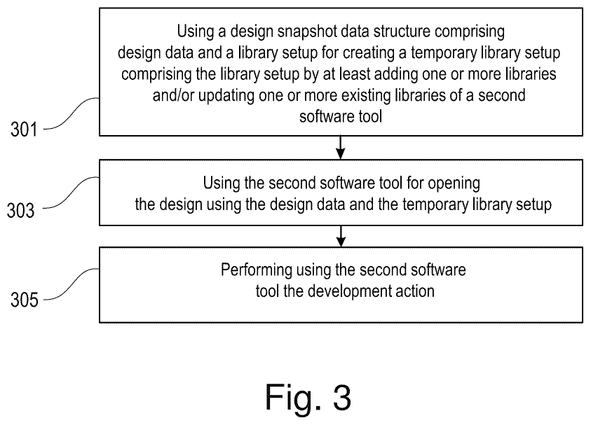

FIG. 3 is a flowchart of a method for performing a development action on a design of an electronic circuit system using a second software tool according to an example of the present subject matter. For the purpose of explanation, the method described in FIG. 3 may be implemented in the system illustrated in FIG. 1 but is not limited to this implementation. The method may, for example, be performed by the second computer system 102.

A design snapshot data structure comprising entries representing design data and a library setup may be used in step 301 for creating a temporary library setup comprising the library setup. The temporary library setup may be created by at least adding one or more libraries and/or updating one or more existing libraries of a second software tool.

The second software tool may be used in step 303 for opening the design using the design data and the temporary library setup.

The second software tool may be used in step 305 for performing the development action.

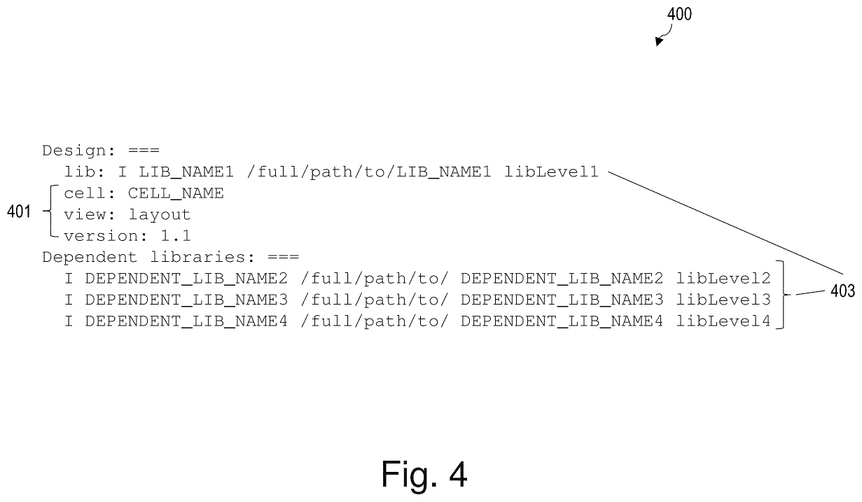

FIG. 4 depicts a diagram that represents a design snapshot data structure 400 in accordance with an example of the present subject matter. In this example, the software tool of an EDA environment has been used to develop a design that is represented by the design snapshot data structure. The diagram of the design snapshot data structure 400 captures the elements of the design and its associated dependencies.

First entries 401 indicates the top level cell being referenced is CELL_NAME. The first entries 401 further indicate that the design is being worked on in its layout view, which refers to the physical representation of the electronic circuit system, and the current version is identified as 1.1, indicating a specific iteration of the design.

Additionally, second entries 403 indicate the library setup. Specifically, the second entries 403 specifies that the primary library used is LIB_NAME1 (version libLevel1), located at /full/path/to/LIB_NAME1. The second entries 403 further list dependent libraries necessary for the design's functionality: DEPENDENT_LIB_NAME2 (version libLevel2), DEPENDENT_LIB_NAME3 (version libLevel3), and DEPENDENT_LIB_NAME4 (version libLevel3), each with defined paths. These paths and version numbers may ensure that the design can be accurately reconstructed or shared across different instances or systems, guaranteeing that the design and its dependencies remain consistent and compatible. This snapshot approach aids in preserving the design's integrity, making collaboration and version control more efficient, and ensuring that all necessary libraries are readily available. In one example, the design snapshot data structure 400 may further include an entry comprising metadata descriptive of the software tool such as a version of the software tool and its configuration settings. The design snapshot data structure 400 may further include an entry containing time information, such as a timestamp, to indicate the specific point in time during the development process, capturing the state of the design at that moment.

The present subject matter may comprise the following clauses.
Clause 1. A method for developing a design of an electronic circuit system in one or more Electronic Design Automation (EDA) environments; the method comprising: receiving data indicative of an event related to a specific point in time during development of the design of the electronic circuit system using a first software tool; determining a development action based on the event; determining design data descriptive of a state the design at the point in time, and determining a library setup descriptive of libraries used by the first software tool to provide the design at that state; creating a design snapshot data structure comprising the design data and the library setup; and sharing the design snapshot data structure with a second software tool for enabling execution of the development action using the second software tool.
Clause 2. The method of clause 1, the development action comprising at least one of: addressing a detected bug representing a design rule violation and/or a bug in the first software tool or incorporating a contribution to the design.
Clause 3. The method of any of the preceding clauses 1 to 2, the first and second software tools being two instances of a software tool of the same EDA environment, the first and second software tools being different tools of different EDA environments.
Clause 4. The method of any of the preceding clauses 1 to 3, the design snapshot data structure further comprising a metadata descriptive of the first software tool.
Clause 5. The method of any of the preceding clauses 1 to 4, the sharing comprising any one of: storing the design snapshot data structure in a shared memory between the first and second software tools; and sending using a workplace messaging platform the design snapshot data structure to the second software tool.
Clause 6. The method of any of the preceding clauses 1 to 5, further comprising: using the shared design snapshot data structure for creating a temporary library setup comprising the library setup by at least adding one or more libraries and/or updating one or more existing libraries of the second software tool; using the second software tool for opening the design using the design data and the temporary library setup; and performing using the second software tool the development action.
Clause 7. The method of clause 6, wherein the creating of the temporary library setup and the opening of the design is automatically performed using a library manager that is configured to connect to the second software tool through an interface.
Clause 8. The method of clause 7, the interface being a web interface, wherein the shared design snapshot data structure is provided as a link to the interface, wherein the creating of the temporary library setup and the opening of the design is automatically performed in response to invoking the link.
Clause 9. The method of any of the preceding clauses 1 to 8, the design data being descriptive of a first cell representing the design, wherein the library setup includes libraries for the first cell and one or more second cells representing components of the design.
Clause 10. The method of clause 9, wherein the libraries are determined by navigation in accordance with a design architecture of the design of the first and second cells.
Clause 11. The method of clause 10, the design architecture being a hierarchical architecture, wherein the first cell is a top level cell and the second cells are sub hierarchy cells, wherein the navigation is a hierarchical traversal starting from the first cell.
Clause 12. The method of any of the preceding clauses 1 to 11, the first software tool being executed in a first computer system, the second software tool being executed in a second computer system, wherein the first and second computer systems are collocated or remotely connected systems.
Clause 13. The method of any of the preceding clauses 1 to 12, the library setup comprising paths and versions of the libraries.

Computing environment 800 contains an example of an environment for the execution of at least some of the computer code involved in performing the inventive methods, such as code 900 for developing a design of an electronic circuit system using a software tool. In addition to block 900, computing environment 800 includes, for example, computer 801, wide area network (WAN) 802, end user device (EUD) 803, remote server 804, public cloud 805, and private cloud 806. In this embodiment, computer 801 includes processor set 810 (including processing circuitry 820 and cache 821), communication fabric 811, volatile memory 812, persistent storage 813 (including operating system 822 and block 900, as identified above), peripheral device set 814 (including user interface (UI) device set 823, storage 824, and Internet of Things (IoT) sensor set 825), and network module 815. Remote server 804 includes remote database 830. Public cloud 805 includes gateway 840, cloud orchestration module 841, host physical machine set 842, virtual machine set 843, and container set 844.

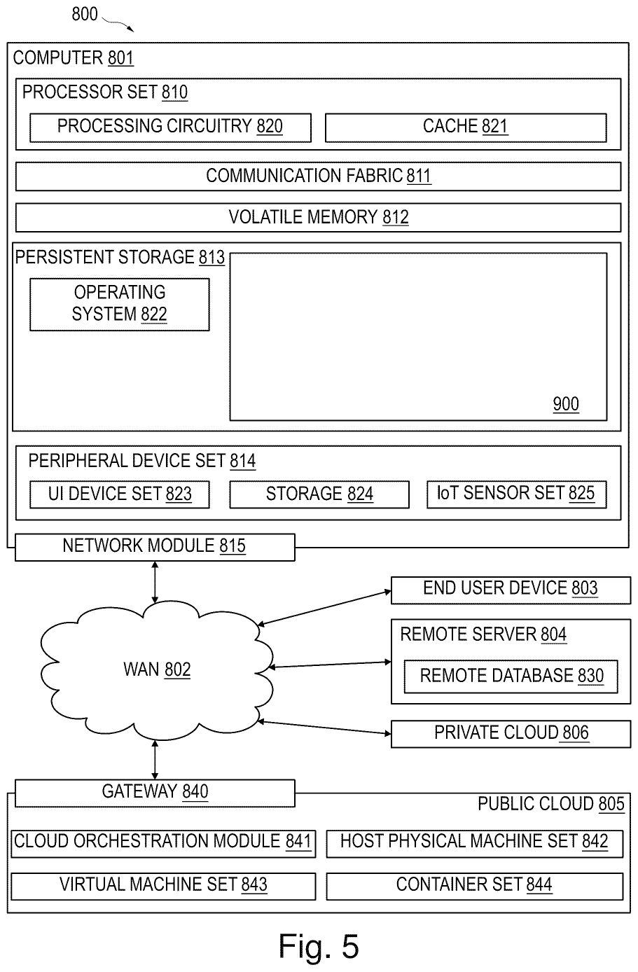

COMPUTER 801 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 830. As is well understood in the art of computer technology, and depending upon the technology, performance of a computer-implemented method may be distributed among multiple computers and/or between multiple locations. On the other hand, in this presentation of computing environment 800, detailed discussion is focused on a single computer, specifically computer 801, to keep the presentation as simple as possible. Computer 801 may be located in a cloud, even though it is not shown in a cloud in FIG. 5. On the other hand, computer 801 is not required to be in a cloud except to any extent as may be affirmatively indicated.

PROCESSOR SET 810 includes one, or more, computer processors of any type now known or to be developed in the future. Processing circuitry 820 may be distributed over multiple packages, for example, multiple, coordinated integrated circuit chips. Processing circuitry 820 may implement multiple processor threads and/or multiple processor cores. Cache 821 is memory that is located in the processor chip package(s) and is typically used for data or code that should be available for rapid access by the threads or cores running on processor set 810. Cache memories are typically organized into multiple levels depending upon relative proximity to the processing circuitry. Alternatively, some, or all, of the cache for the processor set may be located “off chip.” In some computing environments, processor set 810 may be designed for working with qubits and performing quantum computing.

Computer readable program instructions are typically loaded onto computer 801 to cause a series of operational steps to be performed by processor set 810 of computer 801 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 821 and the other storage media discussed below. The program instructions, and associated data, are accessed by processor set 810 to control and direct performance of the inventive methods. In computing environment 800, at least some of the instructions for performing the inventive methods may be stored in block 900 in persistent storage 813.

COMMUNICATION FABRIC 811 is the signal conduction path that allows the various components of computer 801 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 812 is any type of volatile memory now known or to be developed in the future. Examples include dynamic type random access memory (RAM) or static type RAM. Typically, volatile memory 812 is characterized by random access, but this is not required unless affirmatively indicated. In computer 801, the volatile memory 812 is located in a single package and is internal to computer 801, but, alternatively or additionally, the volatile memory may be distributed over multiple packages and/or located externally with respect to computer 801.

PERSISTENT STORAGE 813 is any form of non-volatile storage for computers that is now known or to be developed in the future. The non-volatility of this storage means that the stored data is maintained regardless of whether power is being supplied to computer 801 and/or directly to persistent storage 813. Persistent storage 813 may be a read only memory (ROM), but typically at least a portion of the persistent storage allows writing of data, deletion of data and re-writing of data. Some familiar forms of persistent storage include magnetic disks and solid state storage devices. Operating system 822 may take several forms, such as various known proprietary operating systems or open source Portable Operating System Interface-type operating systems that employ a kernel. The code included in block 900 typically includes at least some of the computer code involved in performing the inventive methods.

PERIPHERAL DEVICE SET 814 includes the set of peripheral devices of computer 801. Data communication connections between the peripheral devices and the other components of computer 801 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 823 may include components such as a display screen, speaker, microphone, wearable devices (such as goggles and smart watches), keyboard, mouse, printer, touchpad, game controllers, and haptic devices. Storage 824 is external storage, such as an external hard drive, or insertable storage, such as an SD card. Storage 824 may be persistent and/or volatile. In some embodiments, storage 824 may take the form of a quantum computing storage device for storing data in the form of qubits. In embodiments where computer 801 is required to have a large amount of storage (for example, where computer 801 locally stores and manages a large database) then this storage may be provided by peripheral storage devices designed for storing very large amounts of data, such as a storage area network (SAN) that is shared by multiple, geographically distributed computers. IoT sensor set 825 is made up of sensors that can be used in Internet of Things applications. For example, one sensor may be a thermometer and another sensor may be a motion detector.

NETWORK MODULE 815 is the collection of computer software, hardware, and firmware that allows computer 801 to communicate with other computers through WAN 802. Network module 815 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 815 are performed on the same physical hardware device. In other embodiments (for example, embodiments that utilize software-defined networking (SDN)), the control functions and the forwarding functions of network module 815 are performed on physically separate devices, such that the control functions manage several different network hardware devices. Computer readable program instructions for performing the inventive methods can typically be downloaded to computer 801 from an external computer or external storage device through a network adapter card or network interface included in network module 815.

WAN 802 is any wide area network (for example, the internet) capable of communicating computer data over non-local distances by any technology for communicating computer data, now known or to be developed in the future. In some embodiments, the WAN 802 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 803 is any computer system that is used and controlled by an end user (for example, a customer of an enterprise that operates computer 801), and may take any of the forms discussed above in connection with computer 801. EUD 803 typically receives helpful and useful data from the operations of computer 801. For example, in a hypothetical case where computer 801 is designed to provide a recommendation to an end user, this recommendation would typically be communicated from network module 815 of computer 801 through WAN 802 to EUD 803. In this way, EUD 803 can display, or otherwise present, the recommendation to an end user. In some embodiments, EUD 803 may be a client device, such as thin client, heavy client, mainframe computer, desktop computer and so on.

REMOTE SERVER 804 is any computer system that serves at least some data and/or functionality to computer 801. Remote server 804 may be controlled and used by the same entity that operates computer 801. Remote server 804 represents the machine(s) that collect and store helpful and useful data for use by other computers, such as computer 801. For example, in a hypothetical case where computer 801 is designed and programmed to provide a recommendation based on historical data, then this historical data may be provided to computer 801 from remote database 830 of remote server 804.

PUBLIC CLOUD 805 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 805 is performed by the computer hardware and/or software of cloud orchestration module 841. The computing resources provided by public cloud 805 are typically implemented by virtual computing environments that run on various computers making up the computers of host physical machine set 842, which is the universe of physical computers in and/or available to public cloud 805. The virtual computing environments (VCEs) typically take the form of virtual machines from virtual machine set 843 and/or containers from container set 844. It is understood that these VCEs may be stored as images and may be transferred among and between the various physical machine hosts, either as images or after instantiation of the VCE. Cloud orchestration module 841 manages the transfer and storage of images, deploys new instantiations of VCEs and manages active instantiations of VCE deployments. Gateway 840 is the collection of computer software, hardware, and firmware that allows public cloud 805 to communicate through WAN 802.

Some further explanation of virtualized computing environments (VCEs) will now be provided. VCEs can be stored as “images.” A new active VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 806 is similar to public cloud 805, except that the computing resources are only available for use by a single enterprise. While private cloud 806 is depicted as being in communication with WAN 802, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 805 and private cloud 806 are both part of a larger hybrid cloud.

CLOUD COMPUTING SERVICES AND/OR MICROSERVICES (not separately shown in FIG. 5): private and public clouds are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. “A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

1. A method for developing a design of an electronic circuit system in one or more Electronic Design Automation (EDA) environments; the method comprising:
receiving data indicative of an event related to a specific point in time during development of the design of the electronic circuit system using a first software tool;
determining a development action based on the event;
determining design data descriptive of a state the design at the point in time, and determining a library setup descriptive of libraries used by the first software tool to provide the design at that state;
creating a design snapshot data structure comprising the design data and the library setup; and
sharing the design snapshot data structure with a second software tool for enabling execution of the development action using the second software tool.

2. The method of claim 1, the development action comprising at least one of:
addressing a detected bug representing a design rule violation and/or a bug in the first software tool or incorporating a contribution to the design.

3. The method of claim 1, the first and second software tools being two instances of a software tool of the same EDA environment, the first and second software tools being different tools of different EDA environments.

4. The method of claim 1, the design snapshot data structure further comprising a metadata descriptive of the first software tool.

5. The method of claim 1, the sharing comprising any one of:
storing the design snapshot data structure in a shared memory between the first and second software tools; and
sending using a workplace messaging platform the design snapshot data structure to the second software tool.

6. The method of claim 1, further comprising:
using the shared design snapshot data structure for creating a temporary library setup comprising the library setup by at least adding one or more libraries and/or updating one or more existing libraries of the second software tool;
using the second software tool for opening the design using the design data and the temporary library setup; and
performing using the second software tool the development action.

7. The method of claim 6, wherein the creating of the temporary library setup and the opening of the design is automatically performed using a library manager that is configured to connect to the second software tool through an interface.

8. The method of claim 7, the interface being a web interface, wherein the shared design snapshot data structure is provided as a link to the interface, wherein the creating of the temporary library setup and the opening of the design is automatically performed in response to invoking the link.

9. The method of claim 1, the design data being descriptive of a first cell representing the design, wherein the library setup includes libraries for the first cell and one or more second cells representing components of the design.

10. The method of claim 9, wherein the libraries are determined by navigation in accordance with a design architecture of the design of the first and second cells.

11. The method of claim 10, the design architecture being a hierarchical architecture, wherein the first cell is a top level cell and the second cells are sub hierarchy cells, wherein the navigation is a hierarchical traversal starting from the first cell.

12. The method of claim 1, the first software tool being executed in a first computer system, the second software tool being executed in a second computer system, wherein the first and second computer systems are collocated or remotely connected systems.

13. The method of claim 1, the library setup comprising paths and versions of the libraries.

14. A computer program product for developing a design of an electronic circuit system using a software tool in one or more EDA environments, the computer program product comprising a computer-readable storage medium having computer-readable program code embodied therewith, the computer-readable program code configured for:
receiving data indicative of an event related to a specific point in time during development of the design of the electronic circuit system using a first software tool;
determining a development action based on the event;
determining design data descriptive of a state the design at the point in time, and determining a library setup descriptive of libraries used by the first software tool to provide the design at that state;
creating a design snapshot data structure comprising the design data and the library setup; and
sharing the design snapshot data structure with a second software tool for enabling execution of the development action using the second software tool.

15. A computer system for developing a design of an electronic circuit system using a software tool in one or more EDA environments, the computer system comprising a first software tool; the computer system being configured for:
receiving data indicative of an event related to a specific point in time during development of the design of the electronic circuit system using a first software tool;
determining a development action based on the event;
determining design data descriptive of a state the design at the point in time, and a library setup descriptive of libraries used by the first software tool to provide the design at that state;
creating a design snapshot data structure comprising entries representing the design data and the library setup; and
sharing the design snapshot data structure with a second software tool for enabling execution of the development action using the second software tool.
